(19) United States
(12) Patent Application Publication
(10) Pub. No.: US 2012/0262163 A1
(43) Pub. Date: Oct. 18, 2012

(54) HALL SENSOR FOR CANCELING OFFSET

(75) Inventors: Dong Ok HAN, Suwon (KR); Kyung Uk Kim, Suwon (KR)

(73) Assignee: SAMSUNG ELECTRO-MECHANICS CO., LTD.

(21) Appl. No.: 13/440,709

(22) Filed: Apr. 5, 2012

(30) Foreign Application Priority Data
Apr. 12, 2011 (KR) 10-2011-0033538

(51) Int. Cl. G01R 33/06

(52) U.S. Cl. 324/251

(57) ABSTRACT

There is provided a Hall sensor for canceling an offset, including: a Hall element unit including at least one pair of Hall elements, each having a preset detection direction, and connecting detection terminals of the pair of Hall elements to different paths according to a preset calibration mode and a preset operation mode; and a calibration unit calibrating an offset of a detection voltage in the operation mode of the Hall element unit according to an detection voltage in the calibration mode of the Hall element unit.

### CROSS-REFERENCE TO RELATED APPLICATIONS

This application claims the priority of Korean Patent Application No. 10-2011-0033538 filed on Apr. 12, 2011, in the Korean Intellectual Property Office, the disclosure of which is incorporated herein by reference.

### BACKGROUND OF THE INVENTION

1. Field of the Invention

The present invention relates to a hall sensor for canceling an offset.

2. Description of the Related Art

In general, a hall sensor, a semiconductor element performing magnetic field detection and measurement through the Hall effect, is used in various fields, including those of industrial applications and consumer applications.

A hall sensor is implemented in the form of an integrated circuit to calibrate an offset or any other errors. The hall sensor employs a Hall element generating a voltage between both ends thereof through Lorentz force. Hall elements may be specified to have enhanced characteristics by adjusting various forms, processes, doping concentrations, and the like, but in general, Hall elements are fabricated through a complementary metaloxide semiconductor (CMOS) process. However, it may be difficult to perform a specified process within the CMOS process, so Hall elements therefore tend to be fabricated through the general CMOS process and a generated offset thereof is later canceled.

A Hall sensor employs an amplifier which amplifies a Hall element detection voltage. However, since a voltage level detected in the Hall element is small, a gain of the amplifier is set to be high, and in this case, an offset level is also amplified, making it difficult for the Hall sensor to operate normally.

### SUMMARY OF THE INVENTION

An aspect of the present invention provides a Hall sensor capable of dynamically canceling an offset of a Hall device that may be randomly generated and canceling the offset before the offset is transferred to an amplifier.

According to an aspect of the present invention, there is provided a Hall sensor for canceling an offset, including: a Hall element unit including at least one pair of Hall elements, each having a preset detection direction, and connecting detection terminals of the pair of Hall elements to different paths according to a preset calibration mode and a preset operation mode; and a calibration unit calibrating an offset of a detection voltage in the operation mode of the Hall element unit according to an detection voltage in the calibration mode of the Hall element unit.

The Hall element unit may include: a hall element group including a first Hall element having a first pair of terminals for excitation and a first pair of output terminals and a second Hall element having a second pair of terminals for excitation and a second pair of output terminals, wherein a detection direction of the second Hall element is formed to have a preset angle based on a detection direction of the first Hall element; and a switch group including a first switch connected to a first output terminal among the first pair of output terminals of the first Hall element, a second switch connected to a second output terminal among the first pair of output terminals of the first Hall element, a third switch connected to a second output terminal among the second pair of output terminals of the second Hall element, and a fourth switch connected to a first output terminal among the second pair of output terminals of the second Hall element.

In the calibration mode, the first and second may switch connect the first and second output terminals of the first pair of output terminals to a positive output terminal, while the third and fourth may switch connect the first and second output terminals of the second pair of output terminals to a negative output terminal, and in the operation mode, the first and fourth may switch connect the first output terminal among the first pair of output terminals and the first output terminal among the second pair of output terminals to the positive output terminal, while the second and third may switch connect the second output terminal among the first pair of output terminals and the second output terminal among the second pair of output terminals to the negative output terminal.

The angle may be +90° or −90°.

The calibration unit may include: a comparator comparing levels of input differential signals; a bit counter counting comparison results from the comparator by a preset bit unit; and a digital-to-analog converter (DAC) converting the counted results from digital format to an analog format.

The Hall sensor may further include: an amplification unit amplifying the detection voltages from the Hall element unit.

The calibration unit may control a current level or a voltage level input to the amplification unit.

The Hall sensor may further include: a comparison unit comparing the amplified detection voltage from the amplification unit with a preset reference voltage, and converting a comparison result into a digital signal.

The comparison unit may include a Schmitt trigger.

The Hall element unit may include: a hall element group including a first Hall element having a first pair of terminals for excitation and a first pair of output terminals, a second Hall element having a second pair of terminals for excitation and a second pair of output terminals, a third Hall element including a third pair of terminals for excitation and a third pair of output terminals, and a fourth Hall element including a fourth pair of terminals for excitation and a fourth pair of output terminals, wherein a detection direction of the second Hall element is formed by performing rotation at a preset angle, based on a detection direction of the first Hall element, and a detection direction of the fourth Hall element is formed to have a preset angle based on a detection direction of the third Hall element; and a switch group including a first switch connected to a second output terminal among the first pair of output terminals of the first Hall element and a second output terminal among the third pair of output terminals of the third Hall element, and a second switch connected to a first output terminal among the second pair of output terminals of the second Hall element and a first output terminal among the fourth pair of output terminals of the fourth Hall element.

In the calibration mode, the first switch may connect the second output terminal among the first pair of output terminals and the second output terminal among the third pair of output terminals, together with a first output terminal among the first pair of output terminals and a first output terminal among the third pair of output terminals, to a positive output terminal, while the second switch may connect the first output terminal among the second pair of output terminals and the first output terminal among the fourth pair of output terminals, together with a second output terminal among the second pair of output terminals and a second output terminal among the fourth pair of output terminals, to a negative output terminal, and in the operation mode, the first switch may connect the second output terminal among the first pair of output terminals and the second output terminal among the third pair of output terminals, together with the second output terminal among the second pair of output terminals and the second output terminal among the fourth pair of output terminals, to the positive output terminal, while second switch may connect the first output terminal among the second pair of output terminals and the first output terminal among the fourth pair of output terminals, together with the first output terminal among the first pair of output terminals and the first output terminal among the third pair of output terminals, to the negative output terminals.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a schematic block diagram of a Hall sensor according to an embodiment of the present invention;

FIG. 2 is a schematic configuration view showing an example of a Hall element unit employed in the Hall sensor according to the embodiment of the present invention;

FIG. 3 is a schematic configuration view showing another example of a Hall element unit employed in the Hall sensor according to the embodiment of the present invention;

FIGS. 4A and 4B are graphs each showing offset cancellation characteristics of the Hall sensor according to the embodiment of the present invention in a calibration mode, irrespective of a magnetic field;

FIG. 5 is a schematic configuration view showing an example of the calibration unit employed in the Hall sensor according to the embodiment of the present invention; and

FIG. 6 is a graph showing electrical characteristics of the Hall sensor according to the embodiment of the present invention.

### DETAILED DESCRIPTION OF THE INVENTION

Embodiments of the present invention will now be described in detail with reference to the accompanying drawings. The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the shapes and dimensions of elements may be exaggerated for clarity, and the same reference numerals will be used throughout to designate the same or like components.

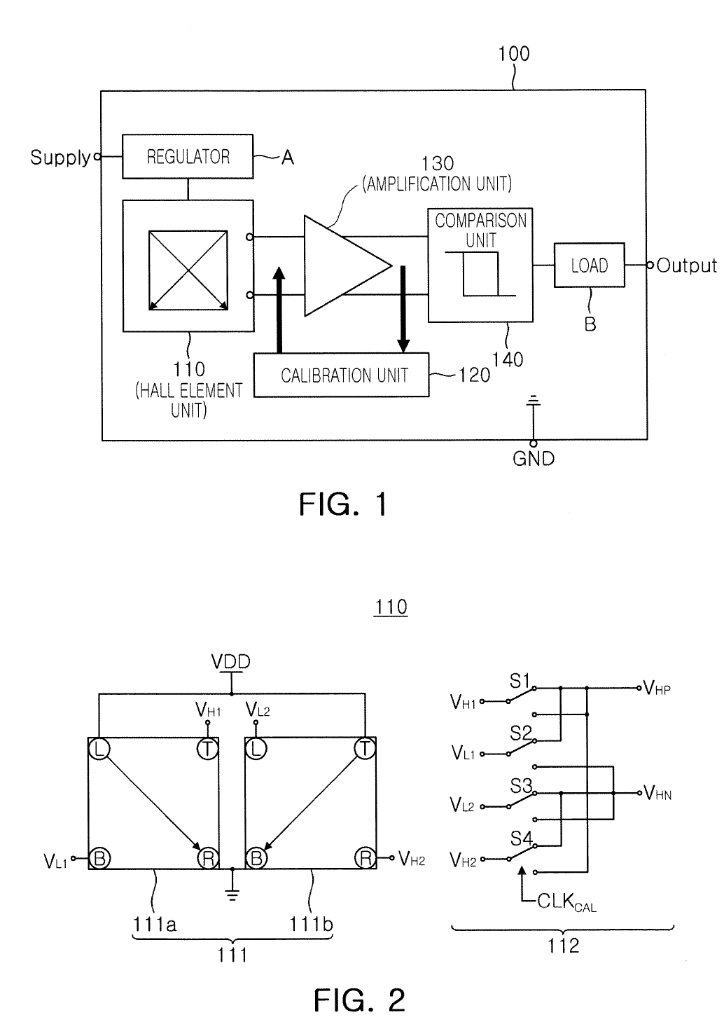

FIG. 1 is a schematic block diagram of a Hall sensor according to an embodiment of the present invention. FIG. 2 is a schematic configuration view showing an example of a Hall element unit employed in the Hall sensor according to the embodiment of the present invention.

With reference to FIGS. 1 and 2, a Hall sensor 100 according to an embodiment of the present invention may include a Hall element unit 110 and a calibration unit 120, and may further include an amplification unit 130 and a comparison unit 140. Also, the Hall sensor 100 according to the embodiment of the present invention may include a regulator A and a load B.

The regulator A may receive a voltage supplied from the outside and generate constant driving power (denoted by VDD in FIG. 2) without a ripple. The generated driving power VDD is used to drive elements within the Hall sensor 100.

The Hall element unit 110 may receive the driving power VDD for excitation from the regulator A, and output first and second detection voltages V_{HP} and V_{HN} in which strength of a magnetic field applied from the outside is detected. The output detection voltages are transferred to the amplifier 130.

The Hall element unit 110 may include a Hall element group including at least one pair of Hall elements 111a and 111b disposed to be adjacent to each other with a predetermined distance on the same plane and a switch group 112 including first to fourth switches S1, S2, S3, and S4 connected to outputs of the pair of Hall elements 111a and 111b. A current may flow through each of the first and second Hall elements 111a and 111b, such that a detection direction in which the magnetic field is detected may rotate at a preset angle. For example, a detection direction of the second Hall element 111b may be formed by performing a +90° or −90° rotation based on a detection direction of the first Hall element 111a.

With reference to FIG. 2, the first Hall element 111a may include a first pair of terminals L and R for excitation and a first pair of first and second output terminals T and B, and the second Hall element 111b may include a second pair of terminals T and B for excitation and a second pair of first and second output terminals L and R.

The terminal L of the first Hall element 111a may be connected to the terminal T of the second Hall element 111b and receive the driving power VDD so as to excite the Hall elements. Meanwhile, the terminal R of the first Hall element 111a may be connected to the terminal B of the second Hall element 111b and be grounded.

Voltages output from the first and second Hall elements 111a and 111b may include first Hall voltages V_{H1} and V_{H2} increasing in accordance with an increase in strength of the magnetic field and second Hall voltages V_{L1} and V_{L2} decreasing in accordance with an increase in strength of the magnetic field.

The first output terminal T of the first Hall element 111a is connected to the first switch S1, the second output terminal B of the first Hall element 111a is connected to the second switch S2, the second output terminal L of the second Hall element 111b is connected to the third switch S3, the first output terminal R of the second Hall element 111b is connected to the fourth switch S4.

The first to fourth switches 51, S2, S3, and S4 may switch transmission paths of the voltages output from the first and second Hall elements in a calibration mode and an operation mode according to a calibration clock signal CLK_{CAL}. Here, the calibration mode refers to a mode in which an offset of the first and second Hall elements is cancelled and only a pure Hall voltage is detected, while the operation mode refers to a mode in which a Hall sensing operation is performed to detect the magnetic field.

In the calibration mode, the first and second switches S1 and S2 may connect the first output terminal T and the second output terminal B of the first pair of output terminals to a positive output terminal from which the first detection voltage V_{HP} is outputted, while the third and fourth switches S3 and S4 may connect the first output terminal R and the second output terminal L of the second pair of output terminals to a negative output terminal from which the second detection voltage V_{HN} is outputted.

Also, in the operation mode, the first and fourth switches S1 and S4 may connect the first output terminal T among the first pair of output terminals and the first output terminal R among the second pair of output terminals, to the positive output terminal, while the second and third switches S2 and S3 may connect the second output terminal B among the first pair of output terminals and the second output terminal L among the second pair of output terminals, to the negative output terminal.

Here, the first Hall voltage V_{H1} of the first Hall element 111a is VCM+Vh+V_{OH1} (Here, VCM is a voltage level corresponding to ½ of the driving power VDD supplied in order to drive the first Hall element, Vh is a detection voltage of the first Hall element, and V_{OH1} is an offset voltage applied to an output from the first Hall element) and the second Hall voltage V_{L1} of the first Hall element 111a is VCM-Vh. In addition, the first Hall voltage V_{H2} of the second Hall element 111b is VCM+Vh, and the second Hall voltage V_{L2} of the second Hall element 111b is VCM+Vh+V_{OH2} (Here, V_{OH2} is an offset voltage applied to an output from the second Hall element 111b).

In this case, when the first and second switches S1 and S2 are connected to the positive output terminal and the third and fourth switches S3 and S4 are connected to the negative output terminal according to a selection of the calibration mode, the first detection voltage V_{HP} may become V_{H1}+V_{L1} and the second detection voltage V_{HN} may become V_{H2}+V_{L2}. Namely, the first detection voltage V_{HP} is VCM+Vh+V_{OH1}+VCM−Vh=VCM+V_{OH1}/2 and the second detection voltage V_{HN} is VCM−Vh+VCM+Vh+V_{OH2}=VCM+V_{OH2}/2. Accordingly, when the second detection voltage is subtracted from the first detection voltage, only an offset component (V_{OH1}−V_{OH2})/2 is left, and the thus, the calibration unit 120 may confirm the offset component of the first and second Hall elements 111a and 111b. Namely, the calibration unit 120 may cancel the offset component confirmed in the calibration mode from the output of the Hall element unit 110 in a normal mode to transfer only a pure detection voltage to the amplification unit 130.

Meanwhile, another example of the Hall element unit 110 according to the embodiment of the present invention will be explained.

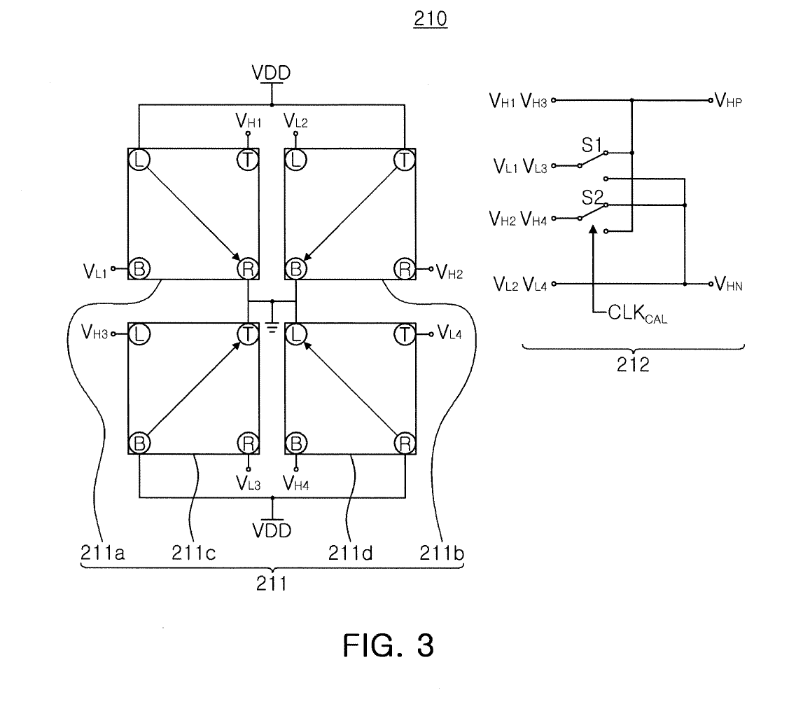

FIG. 3 is a schematic configuration view showing another example of a Hall element unit employed in the Hall sensor according to the embodiment of the present invention.

With reference to FIG. 3, a Hall element unit 210 employed in the Hall sensor according to the embodiment of the present invention may include a Hall element group 211 including first, second, third, and fourth Hall elements 211a, 211b, 211c, and 211d, and a switch group 212 including first and second switches S1 and S2. The respective first, second, third, and fourth Hall elements 211a, 211b, 211c, and 211d may have a detection direction having a preset angle. For example, a detection direction of the second Hall element 211b may be formed by performing a +90° or −90° rotation based on a detection direction of the first Hall element 211a, and a detection direction of the fourth Hall element 211d may be formed by performing a +90° or −90° rotation based on a detection direction of the third Hall element 211c.

The first Hall element 211a may include a first pair of terminals L and R for excitation and a first pair of first and second output terminals T and B. The second Hall element 211b may include a second pair of terminals T and B for excitation and a second pair of first and second output terminals R and L. The third Hall element 211c may include a third pair of terminals B and T for excitation and a third pair of first and second output terminals L and R. The fourth Hall element 211d may include a fourth pair of terminals R and L and a fourth pair of first and second output terminals B and T.

The terminal L of the first Hall element 211a may be connected to the terminal T of the second Hall element 211b and receive driving power VDD so as to excite the Hall elements, and the terminal L of the third Hall element 211c may be connected to the terminal R of the fourth Hall element 211d and receive the driving power VDD so as to excite the Hall elements. Meanwhile, the terminal R of the first Hall element 211a, the terminal B of the second Hall element 211b, the terminal T of the third Hall element 211c, and the terminal L of the fourth Hall element 211d may be connected and be grounded.

The second output terminal B of the first Hall element 211a and the second output terminal R of the third Hall element 211c may be connected to the first switch S1, and the first output terminal R of the second Hall element 211b and the first output terminal B of the fourth Hall element 211d may be connected to the second switch S2.

The first output terminal T of the first Hall element 211a and the first output terminal L of the third Hall element may be connected to a positive output terminal from which the first detection voltage V_{HP} is outputted, and the second output terminal L of the second Hall element 211b and the second output terminal T of the fourth hall element 211d may be connected to a negative output terminal from which the second detection voltage V_{HN} is outputted.

The first and second switches S1 and S2 may switch transmission paths of voltages output from the first to fourth Hall elements in a calibration mode and an operation mode according to the calibration clock signal CLK_{CAL}.

For example, in the calibration mode, the first switch S1 may connect the second output terminal B among the first pair of output terminals and the second output terminal R among the third pair of output terminals, together with the first output terminal T among the first pair of output terminals and the first output terminal L among the third pair of output terminals, to the positive output terminal, while the second switch S2 may connect the first output terminal R among the second pair of output terminals and the first output terminal B among the fourth pair of output terminals, together with the second output terminal L among the second pair of output terminals and the second output terminal T among the fourth pair of output terminals, to the negative output terminal.

In the operation mode, the first switch S1 may connect the second output terminal B among the first pair of output terminals and the second output terminal R among the third pair of output terminals, together with the second output terminal L among the second pair of output terminal and the second output terminal T among the fourth pair of output terminals, to the positive output terminal, while the second switch S2 may connect the first output terminal R among the second pair of output terminals and the first output terminal B among the fourth pair of output terminals, together with the first output terminal T among the first pair of output terminals and the first output terminal L among the third pair of output terminals, to the negative output terminal.

Here, a first Hall voltage V_{H1} of the first Hall element 211a is VCM+Vh+V_{OH1} (Here, VCM is a voltage level corresponding to ½ of the driving power VDD supplied in order to drive the first Hall element, Vh is a detection voltage of the first Hall element, and V_{OH1} is an offset voltage applied to an output from the first Hall element), and a second Hall voltage V_{L1} of the first Hall element 211a is VCM-Vh. A first Hall voltage V_{H2} of the second Hall element 211b is VCM+Vh, and a second Hall voltage V_{H2} of the second Hall element 211b is VCM+Vh+V_{OH2} (Here, V_{OH2} is an offset voltage applied to an output from the second Hall element 111b). In addition, a first Hall voltage V_{H3} of the third Hall element 211c is VCM+Vh+V_{OH3} (Here, V_{OH3} is an offset voltage applied to an output from the third Hall element 211c), and a second Hall voltage V_{L3} of the third Hall element 211c is VCM−Vh. A first Hall voltage V_{H4} of the fourth Hall element 211d is VCM+Vh, and a second Hall voltage V_{L4} of the fourth Hall element 211d is VCM+Vh+V_{OH4} (Here, V_{OH4} is an offset voltage applied to an output from the fourth Hall element 211d).

The offset voltage cancelation of the Hall elements is similar to that in the above description with reference to FIG. 2, so a description thereof will be omitted.

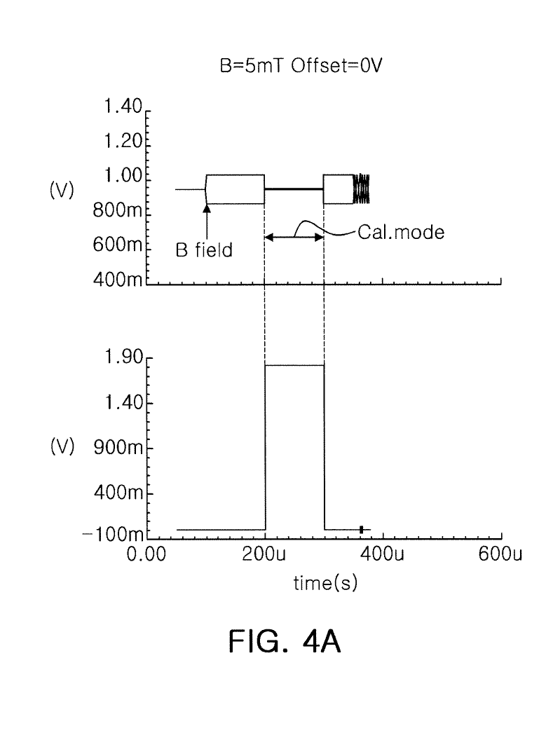

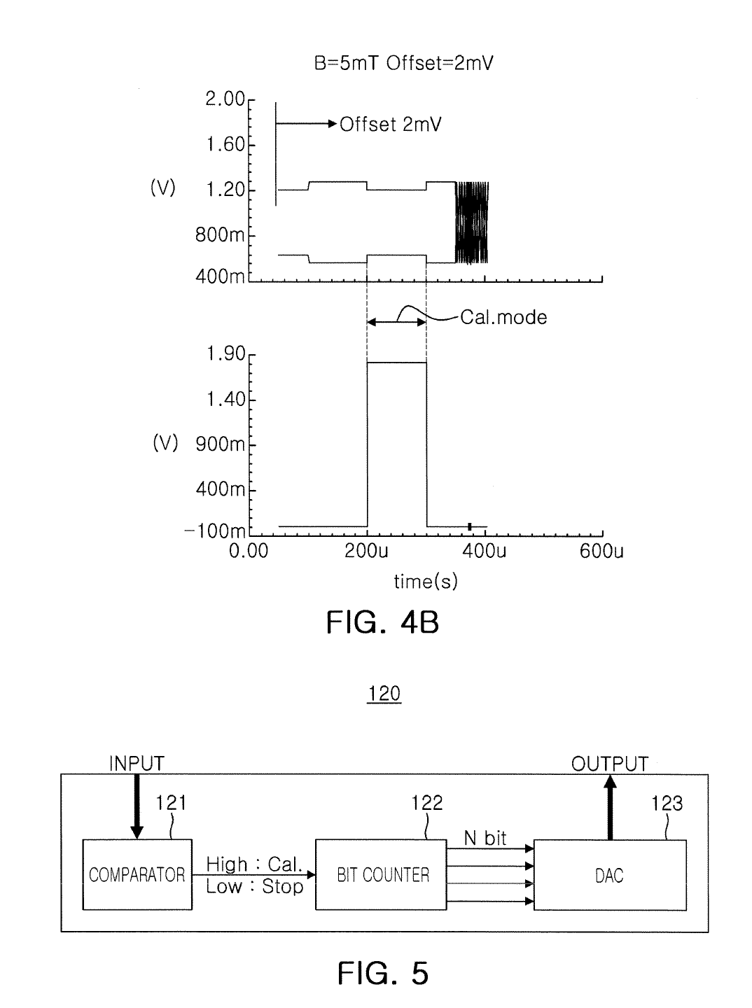

FIGS. 4A and 4B are graphs each showing offset cancellation characteristics of the Hall sensor according to the embodiment of the present invention in a calibration mode, irrespective of a magnetic field.

With reference to FIGS. 4A and 4B, in the graph of FIG. 4A, it can be seen that when there is no offset in the Hall element, and a magnetic field of 5 mT is applied to the Hall element, a signal corresponding to 5 mT is not output in the calibration mode in which the calibration clock signal CLK_{CAL} has a high level. Namely, it can be seen that an output signal is not affected by the magnetic field in the calibration mode. In the graph of FIG. 4B, it can be seen that when an offset of 2 mV exists in the Hall element, even in the case of applying a magnetic field of 5 mT to the Hall element, only a signal having an offset level is output in the calibration mode, thereby allowing the offset of the Hall element to be canceled by removing the offset value.

With reference to FIG. 1 again, the amplification unit 130 may amplify the first and second detection voltages V_{HP} and V_{HN} differentially output from the Hall element unit 110 by a certain amplification factor.

The comparison unit 140 may compare the amplified voltage with a preset reference voltage and output a digital signal. For example, the comparison unit 140 may include a Schmitt trigger. The digital signal may be output to the outside through the load B.

As described above, the offset of the Hall element may be canceled prior to a transfer thereof to the amplification unit 130. Meanwhile, the amplification unit 130 may have an offset in itself. The calibration unit 120 may also cancel the offset generated in the amplification unit 130. For example, the calibration unit 130 may cancel the offset of the amplification unit 130 by various methods, such as chopping, auto-zeroing, ping-pong, offset stabilization, or the like.

FIG. 5 is a schematic configuration view showing an example of the calibration unit employed in the Hall sensor according to the embodiment of the present invention.

With reference to FIG. 5, the calibration unit 120 employed in the Hall sensor according to the embodiment of the present invention may include a comparator 121, a bit counter 122, and a digital-to-analog converter (DAC) 123.

The comparator 121 may receive and compare differential output values amplified by the amplification unit 130, and output a High signal according to a difference in the comparison.

The bit counter 122 may perform counting by bits of a preset unit until the High signal becomes a Low signal.

The DAC 123 may control a current value or a voltage value input to the amplification unit 130 according to the counting results.

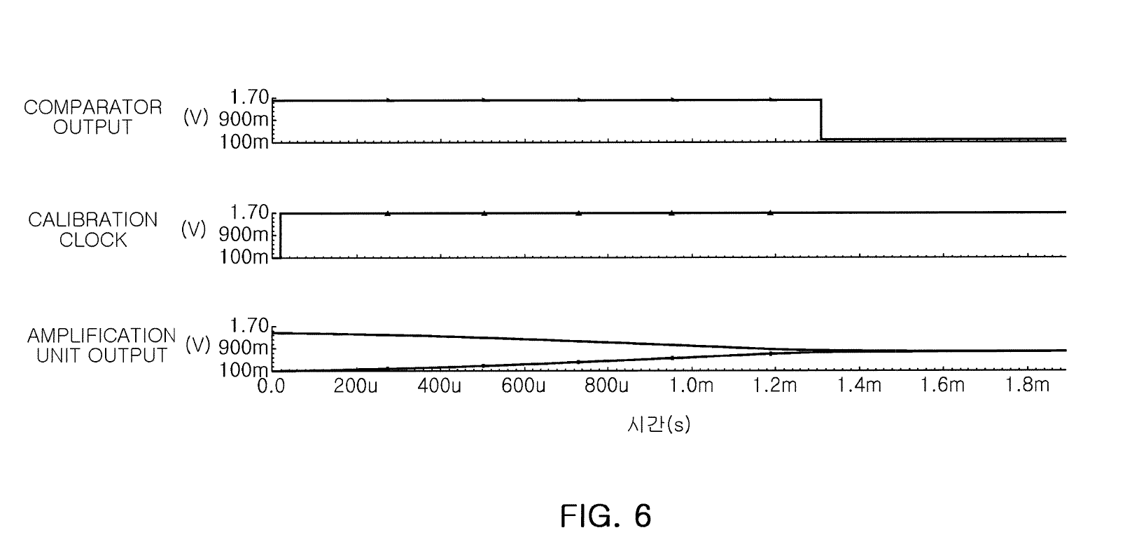

FIG. 6 is a graph showing electrical characteristics of the Hall sensor according to the embodiment of the present invention.

With reference to FIG. 6, when the comparator 121 outputs a High signal, the calibration unit 120 may generate the calibration clock signal CLK_{CAL} to continue an offset cancelation operation after the lapse of a certain time, while when the comparator 121 outputs a Low signal, the calibration unit 120 may stop the offset cancelation operation, whereby the output from the amplification unit 130 may be maintained in an offset cancellation state.

Accordingly, the calibration unit 120 may receive the output from the amplification unit 130, control a voltage value or a current value input to the amplification unit 130 to cancel the offset of the amplification unit 130, such that the offset of the Hall element prior to the transfer thereof to the amplification unit 130 and the offset of the amplification unit may be simultaneously cancelled.

As described above, according to the embodiment of the present invention, at least one pair or two pairs of Hall elements are formed such that a detection direction of one of the Hall elements within a pair has a preset angle, e.g., 90°, based on a detection direction of the other Hall element, and the two or four Hall elements are connected and have different transmission paths in the calibration mode and the operation mode, thereby dynamically canceling an offset which may be randomly generated, canceling an offset of the Hall elements prior to the transfer thereof to the amplification unit, and canceling an offset of the amplification unit in various methods. Therefore, the Hall sensor may be stably driven.

As set forth above, according to embodiments of the invention, at least one pair of Hall elements are formed such that a detection direction of one of the Hall elements has a preset angle based on a detection direction of the other Hall element, and the two Hall elements are connected and have different transmission paths in the calibration mode and the operation mode, thereby dynamically canceling an offset which may be randomly generated, such that an offset of the Hall elements may be cancelled prior to the transfer thereof to the amplification unit.

While the present invention has been shown and described in connection with the embodiments, it will be apparent to those skilled in the art that modifications and variations can be made without departing from the spirit and scope of the invention as defined by the appended claims.

What is claimed is:

1. A Hall sensor for canceling an offset, the Hall sensor comprising:
a Hall element unit including at least one pair of Hall elements, each having a preset detection direction, and connecting detection terminals of the pair of Hall elements to different paths according to a preset calibration mode and a preset operation mode; and
a calibration unit calibrating an offset of a detection voltage in the operation mode of the Hall element unit according to an detection voltage in the calibration mode of the Hall element unit.

2. The Hall sensor of claim 1, wherein the Hall element unit includes:
a hall element group including a first Hall element having a first pair of terminals for excitation and a first pair of output terminals and a second Hall element having a second pair of terminals for excitation and a second pair of output terminals, wherein a detection direction of the second Hall element is formed to have a preset angle based on a detection direction of the first Hall element; and
a switch group including a first switch connected to a first output terminal among the first pair of output terminals of the first Hall element, a second switch connected to a second output terminal among the first pair of output terminals of the first Hall element, a third switch connected to a second output terminal among the second pair of output terminals of the second Hall element, and a fourth switch connected to a first output terminal among the second pair of output terminals of the second Hall element.

3. The Hall sensor of claim 2, wherein, in the calibration mode, the first and second switches connect the first and second output terminals of the first pair of output terminals to a positive output terminal, while the third and fourth switches connect the first and second output terminals of the second pair of output terminals to a negative output terminal, and
in the operation mode, the first and fourth switches connect the first output terminal among the first pair of output terminals and the first output terminal among the second pair of output terminals to the positive output terminal, while the second and third switches connect the second output terminal among the first pair of output terminals and the second output terminal among the second pair of output terminals to the negative output terminal.

4. The Hall sensor of claim 2, wherein the angle is +90° or −90°.

5. The Hall sensor of claim 1, wherein the calibration unit comprises:
a comparator comparing levels of input differential signals;
a bit counter counting comparison results from the comparator by a preset bit unit; and
a digital-to-analog converter (DAC) converting the counted results from digital format to an analog format.

6. The Hall sensor of claim 1, further comprising an amplification unit amplifying the detection voltages from the Hall element unit.

7. The Hall sensor of claim 6, wherein the calibration unit controls a current level or a voltage level input to the amplification unit.

8. The Hall sensor of claim 6, further comprising a comparison unit comparing the amplified detection voltage from the amplification unit with a preset reference voltage, and converting a comparison result into a digital signal.

9. The Hall sensor of claim 8, wherein the comparison unit includes a Schmitt trigger.

10. The Hall sensor of claim 1, wherein the Hall element unit includes:
a hall element group including a first Hall element having a first pair of terminals for excitation and a first pair of output terminals, a second Hall element having a second pair of terminals for excitation and a second pair of output terminals, a third Hall element including a third pair of terminals for excitation and a third pair of output terminals, and a fourth Hall element including a fourth pair of terminals for excitation and a fourth pair of output terminals, wherein a detection direction of the second Hall element is formed by performing rotation at a preset angle, based on a detection direction of the first Hall element, and a detection direction of the fourth Hall element is formed to have a preset angle based on a detection direction of the third Hall element; and
a switch group including a first switch connected to a second output terminal among the first pair of output terminals of the first Hall element and a second output terminal among the third pair of output terminals of the third Hall element, and a second switch connected to a first output terminal among the second pair of output terminals of the second Hall element and a first output terminal among the fourth pair of output terminals of the fourth Hall element.

11. The Hall sensor of claim 10, wherein, in the calibration mode, the first switch connects the second output terminal among the first pair of output terminals and the second output terminal among the third pair of output terminals, together with a first output terminal among the first pair of output terminals and a first output terminal among the third pair of output terminals, to a positive output terminal, while the second switch connects the first output terminal among the second pair of output terminals and the first output terminal among the fourth pair of output terminals, together with a second output terminal among the second pair of output terminals and a second output terminal among the fourth pair of output terminals, to a negative output terminal, and
in the operation mode, the first switch connects the second output terminal among the first pair of output terminals and the second output terminal among the third pair of output terminals, together with the second output terminal among the second pair of output terminals and the second output terminal among the fourth pair of output terminals, to the positive output terminal, while second switch connects the first output terminal among the second pair of output terminals and the first output terminal among the fourth pair of output terminals, together with the first output terminal among the first pair of output terminals and the first output terminal among the third pair of output terminals, to the negative output terminals.

12. The Hall sensor of claim 10, wherein the angle is +90° or −90°.
